(19) United States
(12) Patent Application Publication
(10) Pub. No.: US 2008/0318383 A1
(43) Pub. Date: Dec. 25, 2008

(54) METHOD OF MANUFACTURING SEMICONDUCTOR DEVICE

(75) Inventor: Shingo Ujihara, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/142,320

(22) Filed: Jun. 19, 2008

(30) Foreign Application Priority Data
Jun. 20, 2007 (JP) 2007-162424

(51) Int. Cl. H01L 21/336; H01L 21/28

(52) U.S. Cl. 438/270; 438/589; 257/E21.429; 257/E21.19

(57) ABSTRACT

A method of manufacturing a semiconductor device, including: preparing a semiconductor substrate having an element-isolating film filled in the first trench and an active region; forming a mask-forming film over the semiconductor substrate; forming a first mask having an opening traversing the active region; performing anisotropic etching using the first mask to form a second mask made of the mask-forming film and a second trench having opposite exposed surfaces of the element-isolating film, being shallower than the first trench and being formed in the active region; implanting oxygen ions obliquely using the second mask such that oxygen ions are radiated at a region including a boundary between a surface of the semiconductor substrate inside the second trench and one of the opposite exposed surfaces of the element-isolating film; oxidizing the oxygen ion-implanted region inside the second trench to form an oxidized region; and removing the oxidized region.

### BACKGROUND OF THE INVENTION

1. Field of the Invention

The present invention relates to a method of manufacturing a semiconductor device.

2. Description of the Related Art

With the recent technological advance, there has been progress in the miniaturization of a semiconductor device and, thus, the short channel effect of a transistor has become an issue. Japanese Patent Laid-Open No. 5-167033 discloses a technique to suppress the occurrence of a short channel effect and punch-throughs in a semiconductor device in which side walls of a trench created in a substrate are used as channel regions, by making a distance from the bottom face of the trench to a diffusion layer present in a substrate surface region longer than a planar dimension in a channel direction, even if the dimension is planarly marginal.

In a manufacturing process of a semiconductor device having trench gates, leftovers of a substrate material to be removed occur near a boundary between a semiconductor substrate and an STI (Shallow Trench Isolation) in bottoms of trenches for the trench gates, when forming the trenches in the semiconductor substrate by etching. Consequently, there has been the problem that a gate length shortens locally. With a method of preventing the occurrence of such a leftover by improving etching conditions in a trench forming step, it has been difficult to solve this problem for reasons of constraints on a selection ratio to a mask and to an STI and on a trench shape.

### SUMMARY OF THE INVENTION

An object of the present invention is to provide a semiconductor device superior in device characteristics by a simple method.

According to an aspect of the present invention, there is provided a method of manufacturing a semiconductor device, including:

preparing a semiconductor substrate including a first trench, an element-isolating film buried in the first trench, and an active region surrounded by the element-isolating film;

forming a mask-forming film over the semiconductor substrate; forming, over the mask-forming film, a first mask having a first opening traversing the active region;

performing anisotropic etching using the first mask to form
a second mask having a second opening corresponding to the first opening, the second mask being formed of the mask-forming film, and
a second trench having opposite exposed surfaces of the element-isolating film, the second trench being shallower than the first trench and being formed in the active region;

implanting oxygen ions obliquely in the second trench using the second mask such that oxygen ions are radiated at a region including a boundary between a surface of the semiconductor substrate inside the second trench and one of the opposite exposed surfaces of the element-isolating film;

oxidizing the oxygen ion-implanted region inside the second trench to form an oxidized region; and

removing the oxidized region.

According to another aspect of the present invention, there is provided the above-mentioned method of manufacturing a semiconductor device, wherein oxidization on a surface of the semiconductor substrate including the inside of the second trench is conducted so as to form the oxidized region formed by oxidizing the oxygen ion-implanted region inside the second trench, to form an oxide film including the oxidized region; and the oxide film is removed along with the oxidized region.

According to another aspect of the present invention, there is provided the above-mentioned method of manufacturing a semiconductor device, further including:

removing the second mask;

forming a gate insulating film on the semiconductor substrate including the inside of the second trench;

forming a gate electrode by forming a conductive film so as to fill the inside of the second trench in which the gate insulating film is formed, and to pattern the conductive film; and

forming source/drain regions by introducing impurities into the active region on both sides of the gate electrode.

According to another aspect of the present invention, there is provided the above-mentioned method of manufacturing a semiconductor device, wherein the element-isolating film is an oxide silicon film and the mask-forming film is a silicon nitride film.

According to another aspect of the present invention, there is provided a method of manufacturing a trench gate transistor including:

a gate electrode formed inside a trench;

first and second diffusion layer regions formed in a first direction with the gate electrode held therebetween; and

first and second element-isolating regions formed in a second direction perpendicular to the first direction with the gate electrode held therebetween;

the method including:

performing ion implantation into the trench at a predetermined angle with respect to a direction vertical to a semiconductor substrate after forming the trench; and

removing a region of the semiconductor substrate on which the ion implantation has been performed.

According to another aspect of the present invention, there is provided the above-mentioned method of manufacturing a trench gate transistor, further including: forming a mask having a predetermined height, the mask being used for forming the trench, wherein the angle of the ion implantation is controlled according to the height of the mask.

According to another aspect of the present invention, there is provided the above-mentioned method of manufacturing a trench gate transistor, wherein ions used for the ion implantation are oxygen ions.

According to another aspect of the present invention, there is provided a method of manufacturing a semiconductor device, including: forming at least one trench gate transistor using the above-mentioned method.

According to the present invention, it is possible to provide a semiconductor device superior in device characteristics by a simple method.

### BRIEF DESCRIPTION OF THE DRAWINGS

FIG. 1 is a plan view illustrating an example of a semiconductor device manufactured according to the present invention;

FIGS. 2A and 2B are cross-sectional views illustrating a step for explaining an example of a manufacturing method according to the present invention;

FIGS. 3A and 3B are cross-sectional views illustrating a step subsequent to the step of FIGS. 2A and 2B;

FIGS. 4A and 4B are cross-sectional views illustrating a step subsequent to the step of FIGS. 3A and 3B;

FIGS. 5A and 5B are cross-sectional views illustrating a step subsequent to the step of FIGS. 4A and 4B;

FIGS. 6A and 6B are cross-sectional views illustrating a step subsequent to the step of FIGS. 5A and 5B;

FIGS. 7A and 7B are cross-sectional views illustrating a step subsequent to the step of FIGS. 6A and 6B; and

FIGS. 8A and 8B are cross-sectional views illustrating a step subsequent to the step of FIGS. 7A and 7B.

### DETAILED DESCRIPTION OF THE PREFERRED EMBODIMENTS

Now, an explanation will be made of an example of a manufacturing method in accordance with the present invention by taking as an example the manufacture of a dynamic random access memory (DRAM) using a trench gate transistor as a cell transistor.

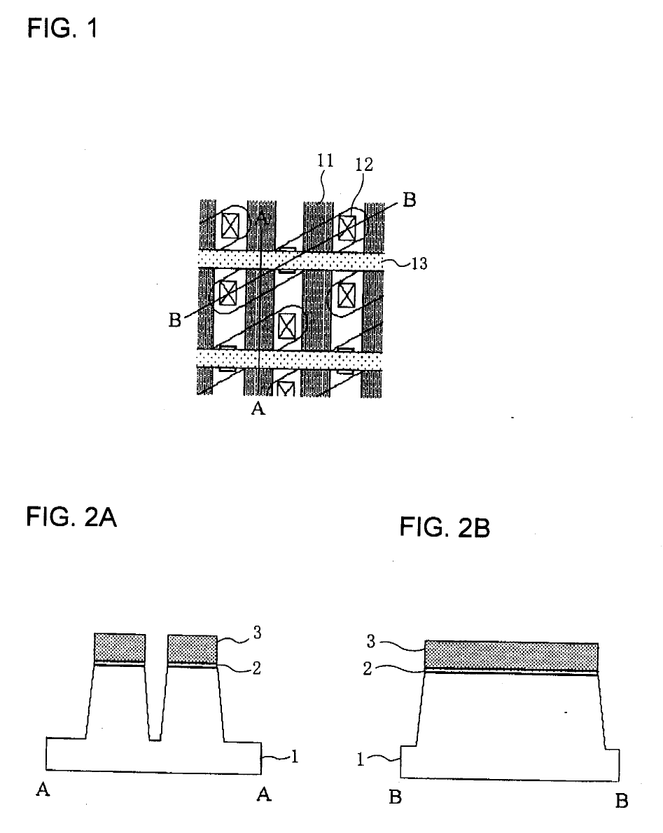

FIG. 1 illustrates a plan view of a DRAM after the formation of bit lines. FIGS. 2A to 8B illustrate cross-sectional views taken along the A-A and B-B lines of FIG. 1 in their respective steps.

First, there is prepared a single-crystal silicon semiconductor substrate 1.

Next, the semiconductor substrate 1 is thermally oxidized to form an approximately 9 nm-thick oxide silicon film 2 on a surface thereof. Then, an approximately 120 nm-thick silicon nitride film 3 is deposited on the oxide silicon film 2 using a chemical vapor deposition (CVD) method.

Next, a resist pattern is formed using a lithography technique and an element-isolating trench is formed in the semiconductor substrate 1, as illustrated in FIGS. 2A and 2B, by sequentially dry-etching the silicon nitride film 3, the oxide silicon film 2 and the semiconductor substrate 1 using this resist pattern as a mask.

Next, an oxide silicon film is deposited over the semiconductor substrate using a CVD process or the like, so as to fill this trench. Then, this oxide silicon film is polished using a chemical mechanical polishing (CMP) method and the oxide silicon film formed outside the element-isolating trench is removed, thereby forming an element-isolating film 4 made of the oxide silicon film buried in the trench. After adjusting the thickness of the element-isolating film 4 using fluorinated acid, the silicon nitride film 3 is removed using hot phosphoric acid.

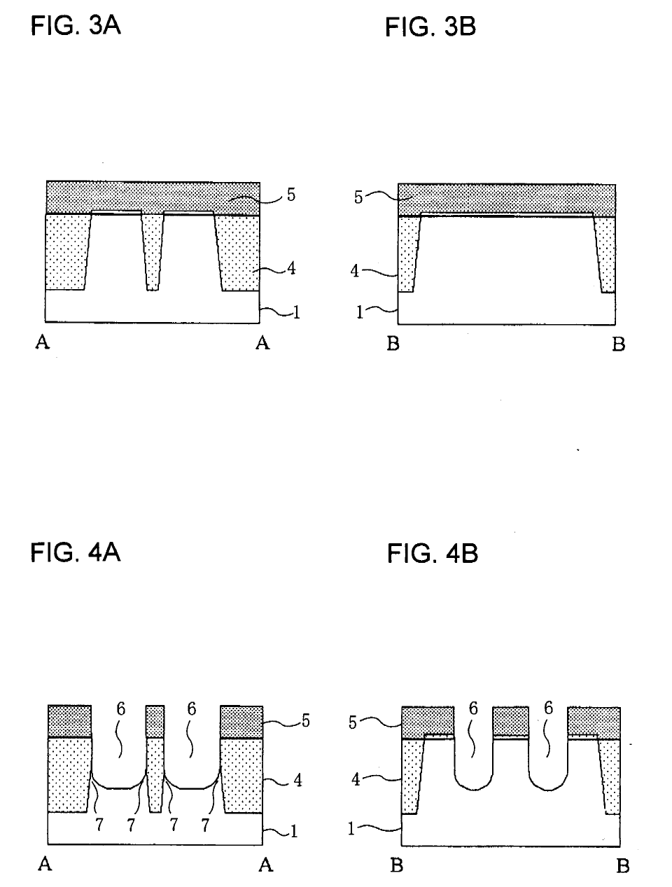

Next, as illustrated in FIGS. 3A and 3B, an approximately 120 nm-thick silicon nitride film 5 is deposited using a CVD process.

Next, a resist pattern is formed using a lithography technique and trenches 6 for trench gates are formed in the semiconductor substrate, as illustrated in FIGS. 4A and 4B, by sequentially dry-etching the silicon nitride film 5, the oxide silicon film 2 and the semiconductor substrate 1 using this resist pattern as a mask. These trenches 6 for trench gates are formed to a depth smaller than the element-isolating trench. These trenches 6 are formed in an active region surrounded by the element-isolating film 4 along a second direction (direction along the A-A line of FIG. 1) intersecting with a first direction (direction along the B-B line of FIG. 1) which is a direction (longitudinal direction) in which the active region extends, so as to traverse the active region. Consequently, both surfaces, among side faces inside these trenches 6, opposed to each other in the second direction are element-isolating film exposed surfaces (FIG. 4A), and both surfaces opposed to each other in the first direction are semiconductor substrate surfaces (FIG. 4B). The bottom faces of the trenches 6 are formed of a semiconductor substrate surface (FIGS. 4A and 4B).

At this time, leftovers of silicon (hereinafter referred to as “silicon burrs”) 7 occur near boundaries between bottom surfaces of the semiconductor substrate inside the trenches 6 and exposed side surfaces of the element-isolating films inside the trenches.

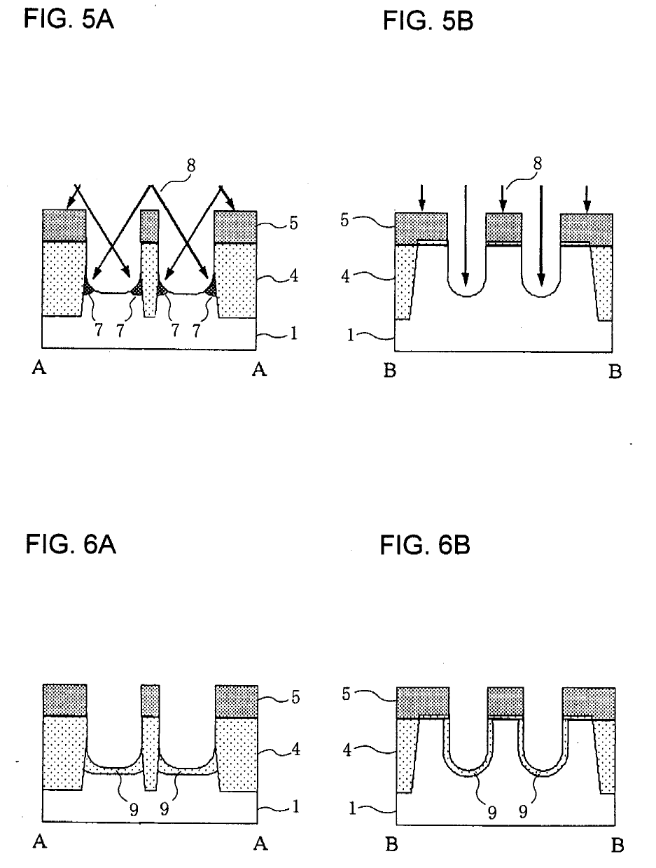

Next, as illustrated in FIGS. 5A and 5B, oxygen ion implantation 8 is performed obliquely from above. In the present exemplary embodiment, oblique ion implantation is performed at a tilt within a plane perpendicular to the B-B line of FIG. 1. In this case, oxygen ions are irradiated perpendicularly to ion-irradiated regions (boundary between the active region and the element-isolating region) in a projection plane corresponding to the plane of FIG. 1. For example, assume that a trench width in a gate direction is 80 nm, a height from the upper surface of the nitride film to the bottom of the trench is 100 nm (the remaining film thickness of the silicon nitride film 5 after silicon etching performed to form the trench 6 is 20 nm and a height from the upper surface of the silicon substrate to the bottom of the trench is 80 nm), and the width of the bottom of silicon burrs is 20 nm. Then, it is possible to set oxygen ion implantation conditions in such a manner that the angle of implantation is θ to 35 to 40° when the vertical direction of the substrate is defined as 0°, the energy of implantation is 5 keV, and the amount of implantation is 1E15 to 1E16 atom/cm².

The angle of oxygen ion implantation can be set using the equation θ=tan⁻¹ (W/H) as a guide, assuming that a trench width in the gate direction is W and a height from the nitride film to the bottom of the trench is H. Thus, it is possible to set the angle of implantation, the energy of implantation and the amount of implantation, as appropriate, according to the shape of the trench, the shape of the silicon burrs, and the thickness of the silicon nitride film 5.

In the implantation of oxygen ions, the silicon nitride film 5 used as a mask when forming the trenches functions as a mask for shutting out oxygen ions implanted obliquely. Thus, oxygen ions are irradiated at silicon burrs 7 and the exposed side surfaces of the element-isolating film inside the trenches, whereas the oxygen ions are not irradiated at any other locations (locations near a middle point along the B-B line of the bottom faces of the trenches and locations outside the trenches, in the present exemplary embodiment).

Next, as illustrated in FIGS. 6A and 6B, a sacrificial oxide film (oxide silicon film) 9 for the removal of damage and contamination in the substrate caused when forming the trench 6 is formed on the substrate surface including the insides of the trenches by thermal oxidization. If oxygen implantation is not performed on the silicon burrs 7, the silicon substrate surface is oxidized almost isotropically. In the present exemplary embodiment, however, the oxidization of the silicon burrs 7 accelerates and the entirety thereof can be oxidized since oxygen ions are implanted in the silicon burrs 7.

Next, the silicon nitride film 5 is removed using hot phosphoric acid, and then the sacrificial oxide film 9 is removed using fluorinated acid. Thus, it is possible to remove the sacrificial oxide film 9 and the oxidized burrs 7.

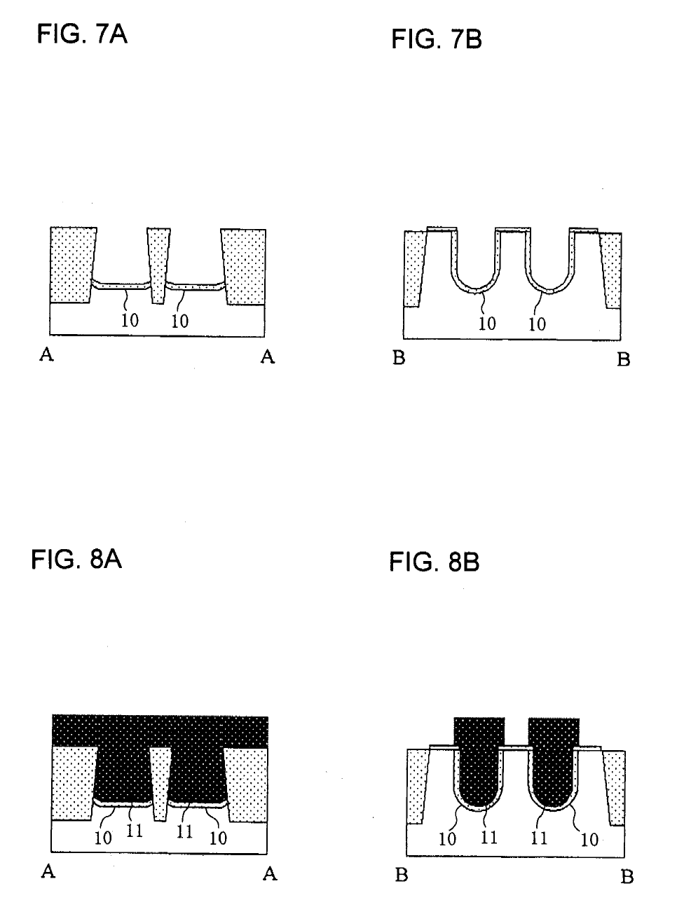

Next, as illustrated in FIGS. 7A and 7B, an approximately 6 nm-thick oxide silicon film (gate insulating film) 10 is formed on the silicon substrate surface inside the trenches 6 by thermal oxidization.

Next, polysilicon containing an impurity is deposited on the gate insulating film 10 using a CVD process, so as to fill the inside of the trench 6. Then, a resist pattern is formed using a lithography technique and a gate electrode 11 is formed using this resist pattern as a mask, as illustrated in FIGS. 8A and 8B, by performing dry etching.

It is possible to set implantation conditions, as appropriate, including dopant species, energy, and a dose amount, in a dopant implantation step for forming wells, transistor channels, sources/drains in the semiconductor substrate. In addition, a DRAM can be completed by forming an interlayer insulating film, contact plugs 12, capacitors, bit lines 13 and the like according to a usual process.

As illustrated in FIGS. 4A and 4B of the present exemplary embodiment, the silicon burrs 7 remain near a boundary between silicon and the element-isolating film in the bottoms of the trenches 6 after etching performed to form trenches for trench gates. According to the present invention, it is possible to implant oxygen ions only in the silicon burrs, as in the example illustrated in FIGS. 5A and 5B, by performing oxygen ion implantation in an oblique direction using the silicon nitride film 5 as a mask. Then, as illustrated in FIGS. 6A and 6B, the oxygen ion-implanted burrs are oxidized when forming the sacrificial oxide film. These oxidized burrs can be removed along with the sacrificial oxide film. The oxygen ion-implanted burrs can also be oxidized by annealing treatment, and the oxidized regions can be easily removed by wet etching using fluorinated acid or the like.

In such a process as described above, it is possible to selectively perform oxygen ion implantation on the insides of the trenches by making use of the mask (silicon nitride film 5) used when forming the trenches for the trench gates, as a mask at the time of oxygen ion implantation. In addition, it is possible to selectively implant oxygen ions in the silicon burrs inside the trenches by obliquely performing oxygen ion implantation, while making use of this mask. Furthermore, after this oxygen ion implantation, it is possible to selectively oxidize silicon burrs inside the trenches in a commonly-practiced oxidization or annealing step. Then, these oxidized burrs can be removed simultaneously by a commonly-practiced step of sacrificial oxide film removal. According to the present exemplary embodiment of the present invention, it is possible to form an excellent trench gate structure by a simple method. As a result, it is possible to manufacture a DRAM superior in device characteristics.

In the above-described exemplary embodiment, an example of a method of manufacturing a semiconductor device has been shown where trench gate transistors are applied to memory cell transistors of a DRAM. However, the present invention is also applicable to a method of manufacturing a trench gate transistor using a semiconducting material, such as silicon, and to a method of manufacturing a semiconductor device having at least one this trench gate transistor, no matter whether the semiconductor device is a memory, a logic device or the like.

What is claimed is:

1. A method of manufacturing a semiconductor device, comprising:
preparing a semiconductor substrate including a first trench, an element-isolating film buried in the first trench, and an active region surrounded by the element-isolating film;
forming a mask-forming film over the semiconductor substrate;
forming, over the mask-forming film, a first mask having a first opening traversing the active region;
performing anisotropic etching using the first mask to form
a second mask having a second opening corresponding to the first opening, the second mask being formed of the mask-forming film, and
a second trench having opposite exposed surfaces of the element-isolating film, the second trench being shallower than the first trench and being formed in the active region;
implanting oxygen ions obliquely in the second trench using the second mask such that oxygen ions are radiated at a region including a boundary between a surface of the semiconductor substrate inside the second trench and one of the opposite exposed surfaces of the element-isolating film;
oxidizing the oxygen ion-implanted region inside the second trench to form an oxidized region; and
removing the oxidized region.

2. The method of manufacturing a semiconductor device according to claim 1, wherein oxidization on a surface of the semiconductor substrate including the inside of the second trench is conducted so as to form the oxidized region formed by oxidizing the oxygen ion-implanted region inside the second trench, to form an oxide film including the oxidized region; and the oxide film is removed along with the oxidized region.

3. The method of manufacturing a semiconductor device according to claim 1, further comprising:
removing the second mask;
forming a gate insulating film on the semiconductor substrate including the inside of the second trench;
forming a gate electrode by forming a conductive film so as to fill the inside of the second trench in which the gate insulating film is formed, and to pattern the conductive film; and
forming source/drain regions by introducing impurities into the active region on both sides of the gate electrode.

4. The method of manufacturing a semiconductor device according to claim 1, wherein the element-isolating film is an oxide silicon film and the mask-forming film is a silicon nitride film.

5. A method of manufacturing a trench gate transistor comprising:
a gate electrode formed inside a trench;
first and second diffusion layer regions formed in a first direction with the gate electrode held therebetween; and
first and second element-isolating regions formed in a second direction perpendicular to the first direction with the gate electrode held therebetween;
the method comprising:
performing ion implantation into the trench at a predetermined angle with respect to a direction vertical to a semiconductor substrate after forming the trench; and
removing a region of the semiconductor substrate on which the ion implantation has been performed.

6. The method of manufacturing a trench gate transistor according claim 5, further comprising: forming a mask having a predetermined height, the mask being used for forming the trench, wherein the angle of the ion implantation is controlled according to the height of the mask.

7. The method of manufacturing a trench gate transistor according to claim 6, wherein ions used for the ion implantation are oxygen ions.

8. A method of manufacturing a semiconductor device, comprising: forming at least one trench gate transistor using the method as recited in claim 7.
